(19) United States
(12) Patent Application Publication
(10) Pub. No.: US 2024/0072004 A1
(43) Pub. Date: Feb. 29, 2024

(54) SEMICONDUCTOR DEVICE WITH CIRCUIT COMPONENTS FORMED THROUGH INTER-DIE CONNECTIONS

(71) Applicant: Micron Technology, Inc., Boise, ID (US)

(72) Inventors: Kyle K. Kirby, Eagle, ID (US); Kunal R. Parekh, Boise, ID (US)

(21) Appl. No.: 18/237,259

(22) Filed: Aug. 23, 2023

Related U.S. Application Data
(60) Provisional application No. 63/401,685, filed on Aug. 28, 2022.

(51) Int. Cl. H01L 25/065; H01L 23/00

(52) U.S. Cl. CPC H01L 25/0657; H01L 24/05; H01L 24/06; H01L 24/08; H01L 24/80; H01L 28/60; H01L 25/18; H01L 2224/05647; H01L 2224/0603; H01L 2224/08145; H01L 2224/80201; H01L 2224/80357; H01L 2224/80379; H01L 2224/80896; H01L 2924/04642; H01L 2924/0504; H01L 2924/0544; H01L 2924/059

(57) ABSTRACT

A semiconductor assembly is described that includes two semiconductor dies. The first semiconductor die includes a first layer of dielectric material at which a first portion of conductive material implementing a first portion of a passive circuit component is at least partially disposed. The second semiconductor die includes a second layer of dielectric material at which a second portion of conductive material implementing a second portion of the passive circuit component is at least partially disposed. A first contact pad at the first layer of dielectric material and a second contact pad at a second layer of dielectric material are coupled to create an interconnect electrically coupling the first semiconductor die and the second semiconductor die. A metal-metal bond is formed between the first portion of the passive circuit component and the second portion of the passive circuit component to create the passive circuit component.

### CROSS-REFERENCE TO RELATED APPLICATION(S)

The present application claims priority to U.S. Provisional Patent Application No. 63/401,685, filed Aug. 28, 2022, the disclosure of which is incorporated herein by reference in its entirety.

### TECHNICAL FIELD

The present disclosure generally relates to semiconductor device assemblies, and more particularly relates to semiconductor devices with circuit components formed through inter-die connections.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIGS. 1A and 1B illustrate simplified schematic cross-sectional views of a series of fabrication steps for semiconductor device assemblies.

FIGS. 2A and 2B illustrate simplified schematic cross-sectional views of a series of fabrication steps for semiconductor device assemblies in accordance with an embodiment of the present technology.

FIGS. 3A and 3B illustrates simplified schematic cross-sectional views of a series of fabrication steps for semiconductor device assemblies in accordance with an embodiment of the present technology.

FIG. 4 illustrates a simplified schematic cross-sectional view of a semiconductor device assembly in accordance with an embodiment of the present technology.

FIG. 5 illustrates a schematic view showing a system that includes a semiconductor device assembly configured in accordance with an embodiment of the present technology.

FIG. 6 illustrates an example method for fabricating a semiconductor device assembly in accordance with an embodiment of the present technology.

### DETAILED DESCRIPTION

Semiconductor devices are integrated in many devices to implement memory cells, processor circuits, imager devices, and other functional features. As more applications for semiconductor devices are discovered, designers are tasked with creating improved devices that can perform a greater number of operations per second, store greater amounts of data, or operate with a higher level of security. To accomplish this task, designers continue to develop new techniques to increase the number of circuit elements on a semiconductor device without increasing the size of the device. This development, however, may not be sustainable due to various challenges that arise from designing semiconductor devices with high circuit density. Thus, additional techniques may be required to continue the growth in capability of semiconductor devices.

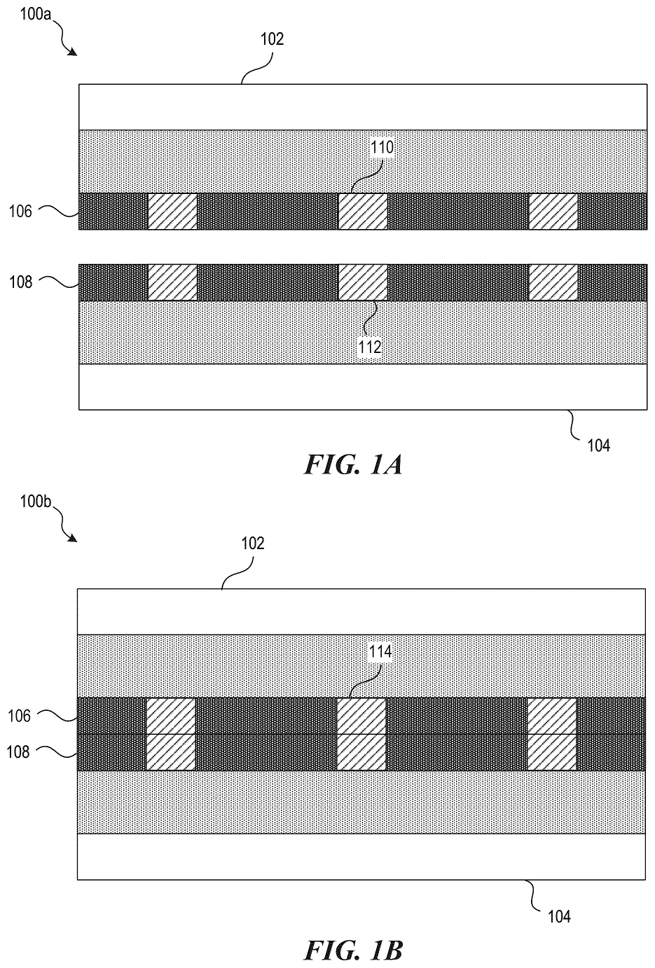

One such technique is to implement multiple semiconductor dies within a single package. These multiple dies may be stacked to increase the number of circuit elements within the package without increasing a footprint (e.g., horizontal area) of the device. Stacked semiconductor devices (e.g., three-dimensional interface (3DI) packaging solutions) are often implemented as a set of multiple semiconductor dies disposed on silicon wafers. Each of the multiple semiconductor dies may include metallization layers that provide various functionality. These semiconductor dies are physically and electronically connected to one another to enable electrical communication between the dies. Many solutions for connecting semiconductor dies, however, may be suboptimal for producing a compact, well-connected semiconductor device. One such semiconductor device assembly is illustrated by way of example in FIGS. 1A and 1B.

Beginning with FIG. 1A, a semiconductor device assembly 100a includes a semiconductor die 102 and a semiconductor die 104. The semiconductor die 102 may include a dielectric layer 106 at a bonding surface of the semiconductor die 102, and the semiconductor die 104 may include a dielectric layer 108 at a bonding surface of the semiconductor die 104. The dielectric layer 106 and the dielectric layer 108 may act as a passivized, outermost portion of the semiconductor dies that insulates circuitry and connections of the semiconductor dies. Contact pads 110 may be placed along portions of the dielectric layer 106, and contact pads 112 may be placed along portions of the dielectric layer 108. The contact pads 110 may be dispersed throughout the dielectric layer 106 such that dielectric material separates each pad. The contact pads 112 may be similarly dispersed throughout the dielectric layer 108. As illustrated, the dielectric material between the contact pads 110 and the contact pads 112 may be undeveloped, and no circuitry may be disposed at these locations.

The semiconductor die 102 and the semiconductor die 104 may be coupled (e.g., stacked) and electrically connected. The semiconductor die 102 and the semiconductor die 104 may electrically couple at the contact pads 110 and the contact pads 112. The contact pads 110 and the contact pads 112 may be coupled to form a bond between a lower surface of the contact pads 110 and an upper surface of the contact pads 112. The coupling process may include heating the semiconductor die 102 and the semiconductor die 104. During the heating, force may be applied to the semiconductor die 102 and the semiconductor die 104 to bring the dielectric layer 106 in contact with the dielectric layer 108 and cause the contact pads 110 and the contact pads 112 to form a connective structure. The resulting semiconductor device assembly is illustrated by way of example in FIG. 1B.

FIG. 1B illustrates an electrically connected semiconductor device assembly 100b. The dielectric layer 106 and the dielectric layer 108 may bond to physically couple the semiconductor die 102 and the semiconductor die 104. The semiconductor die 102 and the semiconductor die 104 are connected through interconnects 114 (e.g., conductive structures). The interconnects 114 may be formed from the contact pads 110 or the contact pads 112 (e.g., through annealing, an intermediate material, etc.). The interconnects 114 may be any appropriate connective structure, for example, a conductive pillar, a solder joint, or any other conductive structure. Functional circuitry may be disposed beneath the dielectric layer 106 and the dielectric layer 108 at the semiconductor die 102 and the semiconductor die 104. This circuitry may couple to the interconnects 114 to electrically couple the semiconductor dies. In doing so, electrical signals may pass from circuitry at the semiconductor die 102 to circuitry at the semiconductor die 104 and vice versa.

The semiconductor device assembly 100b may be suboptimal for producing a compact semiconductor device. For example, the interconnects 114 may be separated by undeveloped dielectric material. The dielectric material may act as an insulator for circuitry at the semiconductor dies. The dielectric material may also provide a bonding surface at which bonds may be formed to mechanically support the coupling of the semiconductor dies. In the semiconductor device assembly 100b, circuit components are not disposed within the dielectric layer 106 or the dielectric layer 108. In this way, these circuit components may be implemented at the die substrate, thereby increasing circuit area and device size required to implement the semiconductor device. Thus, the semiconductor device assembly 100b may be insufficiently compact to be implemented within some electronic devices.

To address these drawbacks and others, a semiconductor assembly is described that includes two semiconductor dies. The first semiconductor die includes a first layer of dielectric material having a first portion of conductive material implementing a first portion of a passive circuit component. The second semiconductor die includes a second layer of dielectric material having a second portion of conductive material implementing a second portion of the passive circuit component. A first contact pad at the first layer of dielectric material and a second contact pad at a second layer of dielectric material are coupled to create an interconnect electrically coupling the first semiconductor die and the second semiconductor die. A metal-metal bond is formed between the first portion of the passive circuit component and the second portion of the passive circuit component to create the passive circuit component. In this way, an efficient, well-connected semiconductor device may be assembled.

The technology disclosed herein relates to semiconductor devices, systems with semiconductor devices, and related methods for manufacturing semiconductor devices. The term “semiconductor device” generally refers to a solid-state device that includes one or more semiconductor materials. Examples of semiconductor devices include logic devices, memory devices, and diodes, among others. Furthermore, the term “semiconductor device” can refer to a finished device or to an assembly or other structure at various stages of processing before becoming a finished device. Depending upon the context in which it is used, the term “substrate” can refer to a structure that supports electronic components (e.g., a die), such as a wafer-level substrate or a die-level substrate, or another die for die-stacking or 3DI applications.

Although some examples may be illustrated or described with respect to dies or wafer, the technology disclosed herein may apply to dies or wafers. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

As used herein, the terms “vertical,” “lateral,” “upper” and “lower” can refer to relative directions or positions of features in the semiconductor die assemblies in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down and left/right can be interchanged depending on the orientation.

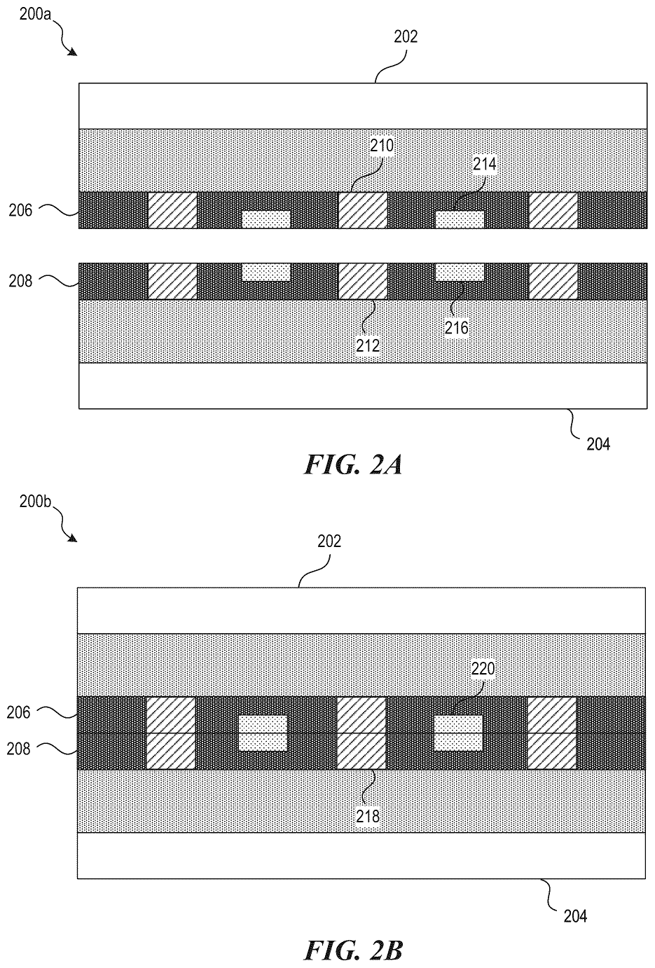

FIGS. 2A and 2B illustrate operations for fabricating a semiconductor device assembly in accordance with an embodiment of the present technology. Beginning with FIG. 2A, a semiconductor device assembly 200a that includes a semiconductor die 202 and a semiconductor die 204 is illustrated. The semiconductor die 202 includes a dielectric layer 206 that acts as a passivation layer to insulate circuitry and connections at the die 202. The dielectric layer 206 may include dielectric material, for example, silicon oxide, silicon nitride, silicon carbide, or silicon carbon nitride. The dielectric layer 206 may be created through any appropriate technique, for example, oxidation or deposition. Conductive material or dielectric material may be disposed at a metallization layer between the dielectric layer 206 and the die substrate to implement traces, lines, vias, transistors, or other circuit elements within the semiconductor die 202. For example, layers of conductive material (e.g., copper, aluminum, tin, silver, gold, alloys of these or other materials, etc.) may be separated by layers of dielectric material (e.g., interlayer dielectric) to separate various circuit components. Similarly, the semiconductor die 204 includes a dielectric layer 208. The semiconductor die 204 may include a die substrate and a metallization layer having circuitry and dielectric layers between the die substrate and the dielectric layer 208.

The semiconductor die 202 may include contact pads 210 at the dielectric layer 206. The semiconductor die 204 may similarly include contact pads 212 at the dielectric layer 208, which correspond to contact pads 210 at the dielectric layer 206. The contact pads 210 and the contact pads 212 may enable interconnects electrically coupling the semiconductor dies to be formed. The semiconductor die 202 may further include a first portion 214 of conductive material at the dielectric layer 206, and the semiconductor die 204 may further include a second portion 216 of conductive material at the dielectric layer 208. The first portion 214 of conductive material may implement a first portion of circuit components, and the second portion of the conductive material 216 may implement a second portion of the circuit components. The circuit components may have an internal resistance. For example, instead of being routing circuitry (e.g., traces, vias, wires, lines, etc.), the passive circuit components may be capacitors, resistors, electromagnetic shields, inductors, or the like.

The first portion 214 of conductive material and the second portion 216 of conductive material may collectively implement the passive circuit components. For example, the circuit components may be bisected across a bond line (e.g., metal-metal bond line, Cu—Cu fusion bond line) of the two dies such that, when coupled, the first portion 214 of conductive material and the second portion 216 of conductive material implement the passive circuit components. The circuit components may be distributed across the semiconductor dies in any proportion. A volume of conductive material in the first portion 214 of conductive material may be the same as or different from a volume of conductive material in the second portion 216 of conductive material. For example, the majority of the conductive material for implementing the circuit components may be located on the semiconductor die 202 or the majority of conductive material for implementing the circuit components may be located on the semiconductor die 204. In this way, the circuit components need not be disposed evenly between the semiconductor die 202 and the semiconductor die 204.

The contact pads 210 may be exposed at a bonding surface of the dielectric layer 206 (e.g., the lower surface as illustrated). The first portion 214 of conductive material may similarly be exposed at the bonding surface of the dielectric layer 206. The contact pads 212 may be exposed at a bonding surface of the dielectric layer 208 (e.g., the upper surface as illustrated). The contact pads 212 may be exposed at a location that corresponds to a location at which the contact pads 210 are exposed. The second portion 216 of conductive material may be exposed at the bonding surface of the dielectric layer 208 and at locations corresponding to the first portion 214 of conductive material. As a result, the contact pads 210 may align with the contact pads 212, and the first portion 214 of conductive material may align with the second portion 216 of conductive material when the first semiconductor die 202 and the second semiconductor die 204 are stacked. In this way, stacking the semiconductor die 202 and the semiconductor die 204 may enable interconnects and the passive circuit components to be formed in the dielectric material between the semiconductor dies.

In some implementations, the bonding surface between the semiconductor dies may be required to include a sufficient amount of dielectric material to ensure that the semiconductor dies remain coupled. The dielectric material may act as a bonding area between the semiconductor dies. In some implementations, the conductive material in the portions of the circuit components and the contact pads may expand when heated to electrically couple the semiconductor dies. In doing so, the conductive material may expand and separate the semiconductor dies if they are not bonded with sufficient strength at the dielectric material. Thus, the bonding surfaces at the dielectric layer 206 and the dielectric layer 208 may include a minimum amount of dielectric material. For example, the exposed bonding surface at the dielectric layer 206 and the dielectric layer 208 may be required to be at least fifty, seventy-five, or ninety percent dielectric material. To ensure that appropriate dielectric material is present at the bonding surfaces, the bonding surfaces may include a maximum amount of conductive material. For example, the portions of conductive material and the contact pads exposed at the bonding surfaces may be no more than fifty, twenty-five, or ten percent of the bonding surfaces.

In some instances, the die coupling and interconnect formation process may include creating a vacuum condition around the semiconductor die 202 and the semiconductor die 204. An inert gas may be applied to the dielectric layer 206 or the dielectric layer 208. The contact pads 210 and the contact pads 212 or the dielectric layer 206 and the dielectric layer 208 may be heated to alter properties of the dielectric material and the conductive material. For example, the dielectric material may become reactive to enable a direct bond between the dielectric layers, and the conductive material may anneal to form a bond between the contact pads or the portions of conductive material. Pressure may be applied to the semiconductor die 202 or the semiconductor die 204 to bond the dielectric layer 206 and the dielectric layer 208, the contact pads 210 and the contact pads 212, or the first portion 214 of conductive material and the second portion 214 of conductive material. In aspects, forming the bonds between the contact pads and the portions of conductive material may be performed concurrently, and thus, additional coupling processes may not be needed to form the circuit components at the dielectric layers. An example of a coupled semiconductor device is illustrated in FIG. 2B.

FIG. 2B illustrates an example semiconductor device assembly 200b that includes the semiconductor die 202 mounted to the semiconductor die 204. In some cases, the dielectric layer 206 may bond to the dielectric layer 208 to mechanically couple the semiconductor dies. The semiconductor dies may be bonded active side-to-active side, back side-to-back side, or active side-to-back side. The contact pads 210 and the contact pads 212 may couple (e.g., through a metal-metal bond or through an intermediate material) to form the interconnects 218 electrically coupling the semiconductor die 202 and the semiconductor die 204. The first portion 214 of conductive material and the second portion 216 of conductive material form a metal-metal bond that couples the first portion 214 of conductive material and the second portion 216 of conductive material to create the passive circuit components 220. The passive circuit components 220 may be embedded in the semiconductor die 202 and the semiconductor die 204. For example, the passive circuit components 220 may be disposed in the dielectric layer 206 and the dielectric layer 208 adjacent to the interconnects 218. The interconnects 218 and the circuit components 220 may be separated by dielectric material at the dielectric layer 206 and the dielectric layer 208. In this way, a connected semiconductor device with circuit components 220 disposed between the dies may be assembled.

The circuit components 220 may be implemented in previously unused areas within the semiconductor device. Additionally, the circuit components 220 may implement any number of circuit components that would be implemented at the die substrate or at a printed circuit board (PCB) in other semiconductor devices. As one example, the circuit components 220 may include capacitors for voltage stabilization or for implementing a filter. Capacitors are commonly implemented within the semiconductor dies and the PCB to support power distribution. Thus, the present technology may enable capacitors in the semiconductor dies or the PCB to be relocated to the dielectric layers between the semiconductor dies. For example, the first portion 214 of conductive material and the second portion 216 of conductive material may implement a first and second plate of a capacitor. One or more of the first and second plates could be split across the first portion 214 of conductive material and the second portion 216 of conductive material. For example, the first portion 214 of conductive material can implement the upper portion of the first and second plates, and the second portion 216 of conductive material can implement the lower portion of the first and second plates. Thus, the first portion 214 of conductive material and the second portion 216 of conductive material can form the first and second plates of the capacitor when a bond (e.g., metal-metal bond) is formed between the portions.

In some cases, the first portion 214 of conductive material could implement the first plate or the second portion 216 of conductive material could implement the second plate (e.g., where the plates are separated by dielectric material). In this way, the first or second plates need not be formed through bonding of the first portion 214 of conductive material and the second portion 216 of conductive material. Alternatively or additionally, the circuit components 220 may implement an electromagnetic shield that protects the circuitry at the semiconductor dies from interferences due to radiation. In aspects, the circuit components 220 may implement any other circuit component that may otherwise be implemented elsewhere in the semiconductor device (e.g., transistors, diodes, resistors, etc.) to increase the circuit density of the semiconductor device.

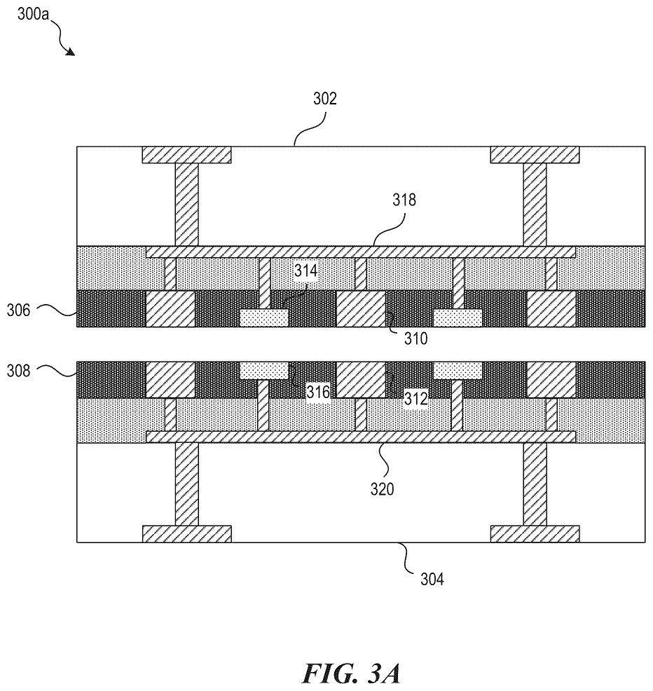

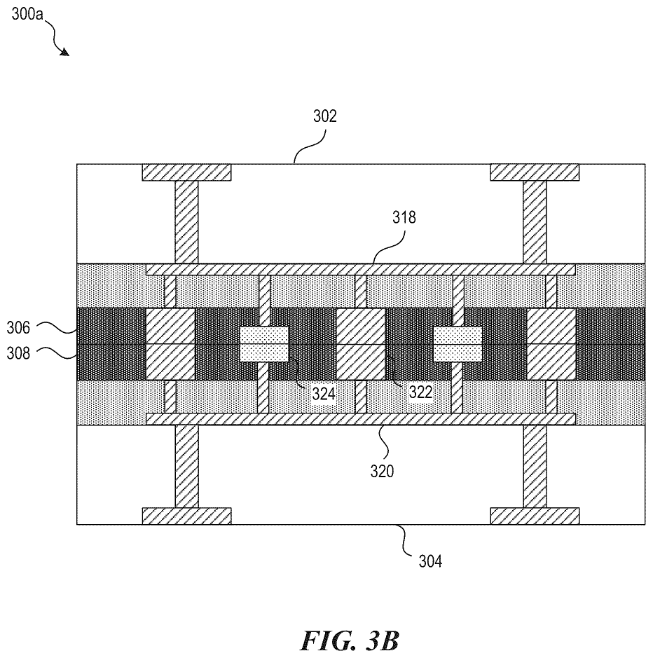

FIGS. 3A and 3B illustrate operations for fabricating a semiconductor device assembly in accordance with an embodiment of the present technology. As illustrated with reference to FIG. 3A, a semiconductor device assembly 300a includes a semiconductor die 302 and a semiconductor die 304. The semiconductor die 302 includes a dielectric layer 306 having contact pads 310 with various circuitry 318, including vias, traces, through-silicon vias (TSVs), and contact pads coupled therewith. The dielectric layer 306 additionally includes a first portion 314 of conductive material that implements a first portion of circuit components to be implemented between the semiconductor die 302 and the semiconductor die 304. The first portion 314 of conductive material may couple with the circuitry 318 to enable the circuitry 318 to transmit and receive signals to and from the circuit components at the dielectric layers 306.

The semiconductor die 304 similarly includes a dielectric layer 308. Contact pads 312 can be disposed at least partially within the dielectric layer 308, and various circuitry 320 can be coupled therewith. A second portion 316 of conductive material (e.g., conductive material reservoirs, contact pads, traces, vias, or other circuitry) that implements a second portion of the circuit components can be implemented at least partially within the dielectric layer 308. The contact pads 312 and the second portion 316 of conductive material correspond to the contact pads 310 and the first portion 314 of conductive material, respectively. The second portion 316 of conductive material may couple with the circuitry 320 to enable the circuitry to transmit and receive electrical signals to and from the circuit components at the dielectric layer 308.

The contact pads 310 or the first portion 314 of conductive material may connect to circuitry 318 in the semiconductor die 302. The circuitry 318 may include one or more vias that connect the contact pads 310 or the first portion 314 of conductive material to various traces, transistors, or other circuitry in the semiconductor die 302. The traces may connect to one or more TSVs that couple to contact pads exposed at a surface of the semiconductor die 302 to enable external connections to additional dies or to a PCB. As a result, electrical signals may be carried from the contact pads 310 to the contact pads at the upper surface or vice versa, and the die circuitry, including the circuit components at the dielectric layer 306, may perform operations using these signals. The contact pads 312 or the second portion 316 of conductive material may similarly connect to circuitry 320 that provides similar functionality.

The semiconductor die 302 and the semiconductor die 304 may be coupled to one another to enable electrical communication between the contact pads 310 and any circuit components coupled therewith and the contact pads 312 and any circuit components connected therewith. The portions of conductive material may also be coupled to form circuit components that may couple to circuitry at the semiconductor die 302, the semiconductor die 304, or any other components coupled therewith. The resulting semiconductor device assembly is illustrated by way of example in FIG. 3B.

FIG. 3B illustrates an example semiconductor device assembly 300b that includes the semiconductor die 302 mounted to the semiconductor die 304. The dielectric layer 306 and the dielectric layer 308 may couple through a direct bond (e.g., dielectric bond) to mechanically couple the semiconductor dies. The semiconductor die 302 and the semiconductor die 304 electrically couple through interconnects 322 formed at the contact pads 310 and the contact pads 312. Given that the interconnects 322 may couple to circuitry at the respective semiconductor dies, electrical signals may be transmitted from the semiconductor die 302 and any circuitry coupled therewith (e.g., another semiconductor die) to the semiconductor die 304 and any circuitry coupled therewith (e.g., a PCB), and vice versa.

Circuit components 324 may also be implemented by forming a bond between the first portion 314 of conductive material and the second portion 316 of conductive material. The circuit components 324 may operate on electrical signals at the semiconductor dies or at any other component in the semiconductor device. For example, the circuit components 324 may include a capacitor that is implemented in a power distribution unit to stabilize voltage or filter electrical signals at the semiconductor dies. Alternatively or additionally, the circuit components 324 may include an electromagnetic shield to protect the circuitry at the semiconductor dies from interferences due to radiation. When the semiconductor die 302 or the semiconductor die 304 implement a memory die, the electromagnetic shield may prevent bit errors within memory. In yet another example, the circuit components 324 may include a transistor that operates using electrical signals at the semiconductor dies. The circuit components 324 may also operate on electrical signals at other components coupled to the semiconductor dies, for example, additional dies or devices coupled to the circuitry 318 or the circuitry 320. In some implementations, the circuitry 318 or the circuitry 320 may not be coupled directly to the circuit components 324. Instead, the circuitry 318 may couple to the circuit components 324 exclusively through the circuitry 320, or vice versa.

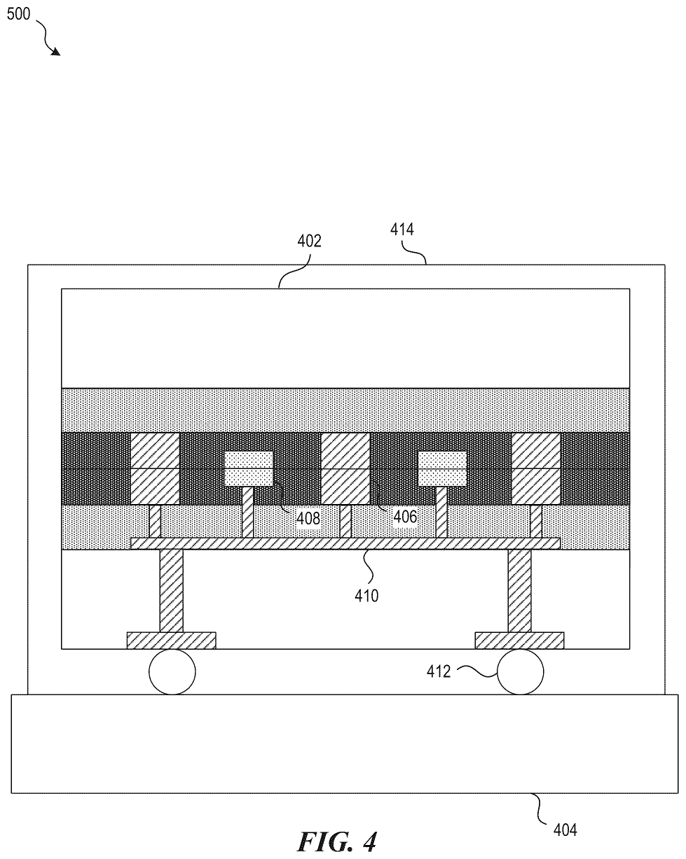

FIG. 4 illustrates a simplified schematic cross-sectional view of a semiconductor device assembly 400 in accordance with an embodiment of the present technology. The semiconductor device assembly 400 includes stacked semiconductor dies 402 assembled onto a package-level substrate 404. The package-level substrate 404 may include a PCB, an interposer, or one or more additional dies. The stacked semiconductor dies 402 may mechanically couple through direct bonds between the dielectric layers of the semiconductor dies. The stacked semiconductor dies 402 may electrically couple (e.g., and mechanically couple) through interconnects 406, which may be formed by annealing conductive material in one or more contact pads to form conductive pillars. The stacked semiconductor dies 402 may further include one or more passive circuit components 408 disposed in an insulation layer between an upper die and a lower die in the stacked semiconductor dies 402. Portions of conductive material at the upper die and the lower die may be bonded through a metal-metal bond to form the circuit components 408. The circuit components 408 may operate on electrical signals at the stacked semiconductor dies 402 or any system components coupled therewith.

The interconnects 406 or the circuit components 408 may couple to various circuitry 410 to provide various connectivity and functionality to the semiconductor device. For example, a base die may include vias that couple the interconnects 406 or the circuit components 408 to traces and other circuitry within the base die. The traces may couple to one or more TSVs that extend to contact pads to provide external connectivity to the stacked semiconductor dies 402. For example, connective structures 412 (e.g., solder balls, copper pillars, etc.) couple the contact pads implemented at the base die and contact pads implemented at the substrate 404. The contact pads at the substrate 404 may couple to various routing circuitry that provides connectivity to one or more internal or external circuit components. Once assembled, the stacked semiconductor dies 402 may be at least partially encapsulated by an encapsulant 414 to protect them from environmental factors (e.g., moisture, particulates, static electricity, and physical impact).

Although in the foregoing example embodiment semiconductor device assemblies have been illustrated and described as including a particular number of semiconductor dies, in other embodiments assemblies can be provided with more or less semiconductor dies. For example, the two-die semiconductor devices illustrated in FIGS. 2 through 4 could be replaced with, e.g., a vertical stack of semiconductor devices, a plurality of semiconductor devices, mutatis mutandis.

In accordance with one aspect of the present disclosure, the semiconductor devices illustrated in the assemblies of FIGS. 2-4 could be memory dies, such as dynamic random-access memory (DRAM) dies, NOT-AND (NAND) memory dies, NOT-OR (NOR) memory dies, magnetic random-access memory (MRAM) dies, phase change memory (PCM) dies, ferroelectric random-access memory (FeRAM) dies, static random-access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

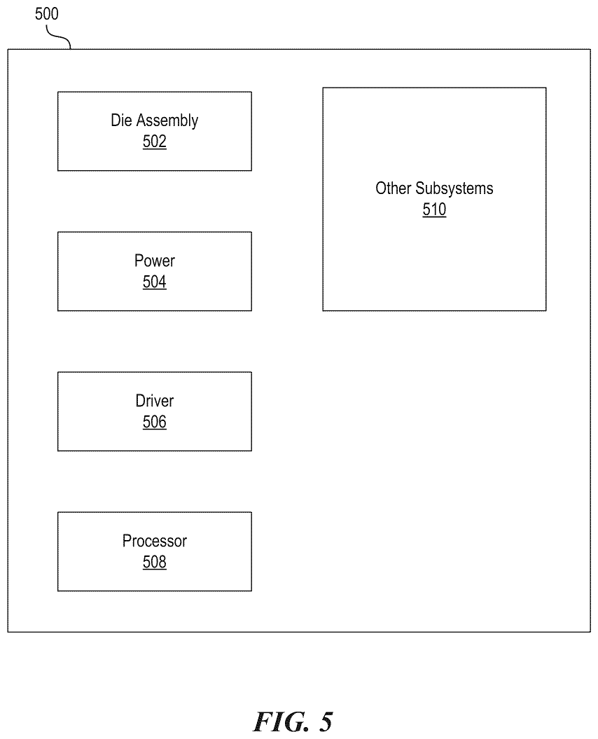

Any one of the semiconductor devices and semiconductor device assemblies described above with reference to FIGS. 2-4 can be incorporated into any of a myriad of larger and/or more complex systems, a representative example of which is system 500 shown schematically in FIG. 5. The system 500 can include a semiconductor device assembly 502 (e.g., or a discrete semiconductor device), a power source 504, a driver 506, a processor 508, and/or other subsystems or components 510. The semiconductor device assembly 502 can include features generally similar to those of the semiconductor devices described above with reference to FIGS. 2-4. The resulting system 500 can perform any of a wide variety of functions, such as memory storage, data processing, and/or other suitable functions. Accordingly, representative systems 500 can include, without limitation, hand-held devices (e.g., mobile phones, tablets, digital readers, and digital audio players), computers, vehicles, appliances and other products. Components of the system 500 may be housed in a single unit or distributed over multiple, interconnected units (e.g., through a communications network). The components of the system 500 can also include remote devices and any of a wide variety of computer-readable media.

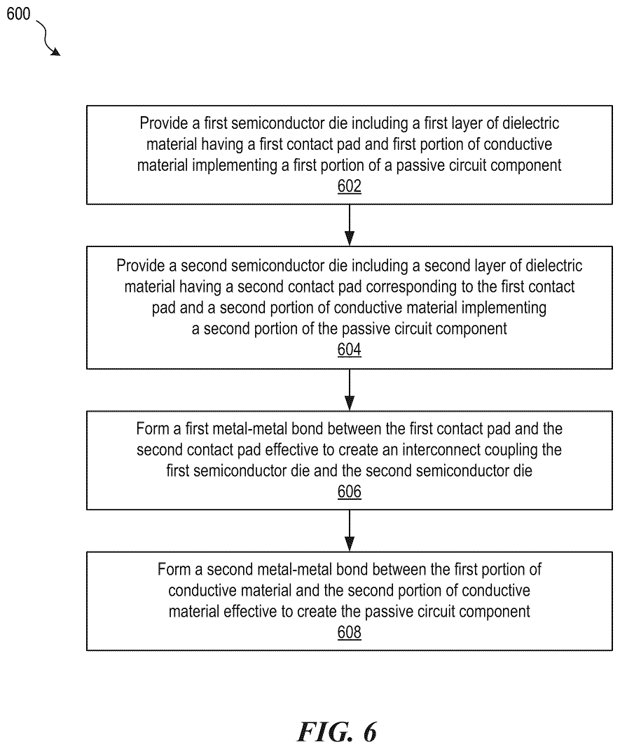

FIG. 6 illustrates an example method 600 for fabricating a semiconductor device assembly in accordance with an embodiment of the present technology. The method 600 may, for illustrative purposes, be described by way of example with respect to features, components, or elements of FIGS. 2-5. Although illustrated in a particular configuration, one or more operations of the method 600 may be omitted, repeated, or reorganized. Additionally, the method 600 may include other operations not illustrated in FIG. 6, for example, operations detailed in one or more other methods described herein.

At 602, a first semiconductor die 202 is provided. The first semiconductor die 202 includes a first dielectric layer 206 having a contact pad 210 and a first portion 214 of conductive material implementing a first portion of a passive circuit component 220 (e.g., capacitor). At 604, a second semiconductor die 204 is provided. The second semiconductor die 204 includes a dielectric layer 208 having a contact pad 212 corresponding to the contact pad 210 and a second portion 216 of conductive material implementing a second portion of the passive circuit component 220. The passive circuit component 220 may be distributed unevenly across the semiconductor die 202 and the semiconductor die 204. For example, a volume of conductive material in the first portion 214 of conductive material may be the same as or different from a volume of conductive material in the second portion 216 of conductive material.

At 606, the contact pad 210 and the contact pad 212 are coupled to form an interconnect 218 electrically coupling the first semiconductor die 202 and the second semiconductor die 204. The contact pad 210 and the contact pad 212 may be heated to anneal conductive material in the contact pads and cause a metal-metal bond to form between the contact pad 210 and the contact pad 212. In aspects, the method 600 may further include mounting the first semiconductor die 202 on the second semiconductor die 204. A bond may be created between the dielectric layer 206 and the dielectric layer 208 to mechanically couple the semiconductor dies. The bond may be created before, during, or after forming an interconnect 218 between the semiconductor dies.

At 608, a metal-metal bond is formed between the first portion 214 of conductive material and the second portion 216 of conductive material to create the passive circuit component 220. The method 600 may include heating the first portion 214 of conductive material and the second portion 216 of conductive material to form the metal-metal bond. In some instances, the passive circuit component may couple to circuitry 318 at the first semiconductor die 202 or circuitry 320 at the semiconductor die 204. This may enable a passive circuit component 220 to be implemented at a layer of dielectric material between two semiconductor dies. Thus, performing the method 600 may fabricate an efficient and well-connected semiconductor device.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A method of making a semiconductor device assembly, comprising:
providing a first semiconductor die including:
a first side;
a first layer of dielectric material disposed at the first side;
a first contact pad disposed at the first side; and
a first portion of conductive material implementing a first portion of a capacitor and disposed at the first side;
providing a second semiconductor die including:
a second side;
a second layer of dielectric material disposed at the second side;
a second contact pad corresponding to the first contact pad and disposed at the second side; and
a second portion of conductive material implementing a second portion of the capacitor and disposed at the second side;
forming a first metal-metal bond between the first contact pad and the second contact pad effective to create an interconnect electrically coupling the first semiconductor die and the second semiconductor die; and
forming a second metal-metal bond between the first portion of conductive material and the second portion of conductive material effective to create the capacitor.

2. The method of claim 1, wherein a volume of conductive material in the first portion of conductive material is different from a volume of conductive material in the second portion of conductive material.

3. The method of claim 1, further comprising forming a bond between the first layer of dielectric material and the second layer of dielectric material.

4. The method of claim 1, further comprising mounting the first semiconductor die on the second semiconductor die.

5. The method of claim 1, further comprising heating the first semiconductor die and the second semiconductor die effective to:
form the first metal-metal bond between the first contact pad and the second contact pad; and
form the second metal-metal bond between the first portion of conductive material and the second portion of conductive material.

6. The method of claim 1, wherein the capacitor is coupled to circuitry of the first semiconductor die exclusively through circuitry of the second semiconductor die.

7. A semiconductor device assembly, comprising:
a first semiconductor die including:
a first side;
a first layer of dielectric material disposed at the first side;
a first contact pad disposed at the first side; and
a first portion of conductive material implementing a first portion of a capacitor and disposed at the first side;
a second semiconductor die including:
a second side;
a second layer of dielectric material disposed at the second side;
a second contact pad corresponding to the first contact pad and disposed at the second side; and
a second portion of conductive material implementing a second portion of the capacitor and disposed at the second side;
an interconnect electrically coupling the first semiconductor die and the second semiconductor die, the interconnect including the first contact pad and the second contact pad; and
the capacitor disposed at the first layer of dielectric material and at the second layer of dielectric material, the capacitor including the first portion of conductive material and the second portion of conductive material,
wherein the first portion of conductive material is coupled to the second portion of conductive material by a metal-metal bond.

8. The semiconductor device assembly of claim 7, wherein the first portion of conductive material and the second portion of conductive material implement a first plate and a second plate of the capacitor.

9. The semiconductor device assembly of claim 7, wherein the first portion of conductive material and the second portion of conductive material comprise copper.

10. The semiconductor device assembly of claim 7, wherein a volume of conductive material in the first portion of conductive material is different from a volume of conductive material in the second portion of conductive material.

11. The semiconductor device assembly of claim 7, wherein a first bonding surface of the first layer of dielectric material is bonded to a second bonding surface of the second layer of dielectric material.

12. The semiconductor device assembly of claim 11, wherein:
the first portion of conductive material is exposed at the first bonding surface;
the first contact pad is exposed at the first bonding surface; and
the first portion of conductive material and the first contact pad cover less than 25 percent of the first bonding surface.

13. The semiconductor device assembly of claim 7, wherein the interconnect and the capacitor are separated by dielectric material.

14. The semiconductor device assembly of claim 7, wherein:
the first semiconductor die further includes first internal circuitry coupled with the capacitor; and
the second semiconductor die further includes second internal circuitry coupled with the capacitor exclusively through the first internal circuitry.

15. The semiconductor device assembly of claim 7, wherein the capacitor is embedded in the first semiconductor die and the second semiconductor die.

16. A semiconductor device assembly, comprising:
a plurality of stacked semiconductor dies, each set of coupled semiconductor dies having an upper semiconductor die and a lower semiconductor die coupled through a coupling,
wherein the coupling comprises:
an interconnect electrically coupling the upper semiconductor die and the lower semiconductor die; and
a capacitor having a first portion disposed on the upper semiconductor die and bonded with a second portion disposed on the lower semiconductor die through a metal-metal bond.

17. The semiconductor device assembly of claim 16, wherein the first portion and the second portion implement a first plate and a second plate of the capacitor.

18. The semiconductor device assembly of claim 16, wherein:
the upper semiconductor die includes first internal circuitry coupled to the capacitor; and
the lower semiconductor die includes second internal circuitry coupled to the capacitor exclusively through the first internal circuitry.

19. The semiconductor device assembly of claim 16, wherein the coupling is disposed in a layer of dielectric material on the upper semiconductor die and a layer of dielectric material on the lower semiconductor die.

20. The semiconductor device assembly of claim 19, wherein the layer of dielectric material on the upper semiconductor die is bonded with the layer of dielectric material on the lower semiconductor die.
